(19) United States
(12) Patent Application Publication
(10) Pub. No.: US 2024/0327201 A1
(43) Pub. Date: Oct. 3, 2024

(54) MEMS DIES EMBEDDED IN GLASS CORES

(71) Applicant: Intel Corporation, Santa Clara, CA (US)

(72) Inventors: Numair Ahmed, Chandler, AZ (US); Mohammad Mamunur Rahman, Gilbert, AZ (US); Suddhasattwa Nad, Chandler, AZ (US); Sashi Kandanur, Chandler, AZ (US); Darko Grujicic, Chandler, AZ (US); Benjamin Duong, Phoenix, AZ (US); Srinivas Pietambaram, Chandler, AZ (US); Tarek Ibrahim, Mesa, AZ (US); Whitney Bryks, Tempe, AZ (US)

(21) Appl. No.: 18/192,576

(22) Filed: Mar. 29, 2023

(51) Int. Cl. B81B 7/00; B81C 1/00; G02B 6/12

(52) U.S. Cl. CPC B81B 7/0048; B81C 1/00325; G02B 6/12004; B81B 2201/0228; B81B 2201/0264; B81B 2201/0271; B81B 2201/0278; B81B 2201/03; B81B 2201/045; B81B 2207/07; B81B 2207/096; B81B 2207/097

(57) ABSTRACT

MEMS dies embedded in glass cores of integrated circuit (IC) package substrates are disclosed. An example integrated circuit (IC) package includes a package substrate including a glass core, the example integrated circuit (IC) package also includes a micro electromechanical system (MEMS) die positioned in a cavity of the glass core.

### FIELD OF THE DISCLOSURE

This disclosure relates generally to integrated circuit packages and, more particularly, to MEMS dies embedded in glass cores.

### BACKGROUND

Integrated circuit (IC) chips and/or semiconductor dies are routinely connected to larger circuit boards such as motherboards and other types of printed circuit boards (PCBs) via a package substrate. IC chips have exhibited increases in interconnect densities as technology has advanced.

### BRIEF DESCRIPTION OF THE DRAWINGS

FIG. 1 illustrates an example integrated circuit (IC) package on a printed circuit board (PCB).

FIG. 2 is a cross-sectional view of an example package substrate that may be implemented in the example IC package of FIG. 1.

FIG. 3 is a flowchart representative of an example method of manufacturing the example package substrate of FIG. 2.

FIGS. 4-11 illustrate different stages in an example method of manufacturing the example package substrate of FIG. 2 detailed in the flowchart of FIG. 3.

FIG. 12 is a cutaway view of another example package substrate.

FIG. 13 is a cutaway view of another example package substrate with an example semiconductor die.

FIG. 14 is a top view of a wafer including dies that may be included in an IC package constructed in accordance with teachings disclosed herein.

FIG. 15 is a cross-sectional side view of an IC device that may be included in an IC package constructed in accordance with teachings disclosed herein.

FIG. 16 is a cross-sectional side view of an IC device assembly that may include an IC package constructed in accordance with teachings disclosed herein.

FIG. 17 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Many known integrated circuit (IC) packages include multiple semiconductor dies (e.g., MEMS dies, optical components, clock oscillators, etc.). Increasing demand on performance for today's ICs is driving the need for integrating greater functionality within a single package. One method of integrating greater functionality in a package is to use the substrate core to integrated functional components within it. Previous solutions to integrate dies or passive components in a substrate core have utilized a single (e.g., monolithic) core in which cavities are drilled to embed the components. Some examples of such solutions include Fan-out Wafer level Packaging (FO-WLP), an Embedded Wafer Level Ball Grid Array (eWLB), Integrated Fan-out (InFO), an Embedded Multi-die Interconnect Bridge (EMIB), etc. In other examples, the core substrate can be formed around the embedded components through an example molding process.

With each advancing technology, controlling package warpage with increasing package size, enabling increased interconnect density within the package and improving device reliability may be needed. In some examples, the organic core of a traditional package can be replaced with a core made of glass. The use of glass may improve scalability by controlling package warpage, increasing package strength, and enabling tighter interconnect density. The integration of glass within a package also may also provide opportunities for integrating active or passive functional elements inside the package core itself to integrate greater functionally.

Examples disclosed herein utilize at least one glass core to embed (e.g., enclose, seal, etc.) a micro electromechanical system (MEMS) dies in an IC package. For example, examples disclosed herein provide heterogeneous integration of MEMS dies in package substrates. In some examples, the integration of MEMS dies can provide high frequency clocks (e.g., timers), improved security, and power consumption, for an example IC package. Examples disclosed herein employ a glass core to provide mechanical strength and stability to an example IC package. Thus, examples disclosed herein reduce substrate warpage and provide increased substrate coplanarity and strength. Further, in examples disclosed herein, the glass cores enable higher density electrical routing through an example IC package. As such, examples disclosed increase the electrical performance of an example IC package.

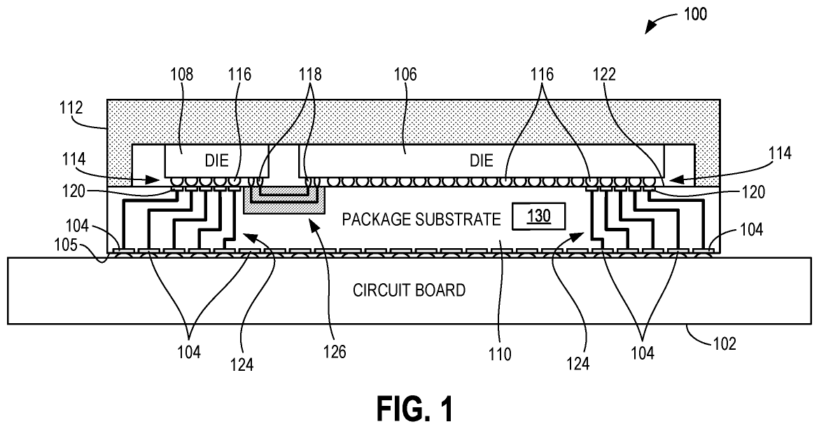

FIG. 1 illustrates an example IC package (e.g., a semiconductor package) 100 constructed in accordance with teachings disclosed herein. In the illustrated example, the IC package 100 is electrically coupled to a circuit board 102 via an array of contact pads or lands 104 on a mounting surface (e.g., a bottom surface) 105 of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, core bumps 116 and bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via internal interconnects 124 within the substrate 110. As a result, there is a complete signal path between the bumps 116 of the dies 106, 108 and the landing pads 104 mounted to the circuit board 102 that pass through the contact pads 120 and the interconnects 124 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge embedded (e.g., example interconnect bridge 126 of FIG. 1) embedded in an underlying substrate (e.g., the package substrate 110). As represented in FIG. 1, core bumps 116 are typically larger than bridge bumps 118. In some examples, the interconnect bridge 126 and the associated bridge bumps 118 are omitted.

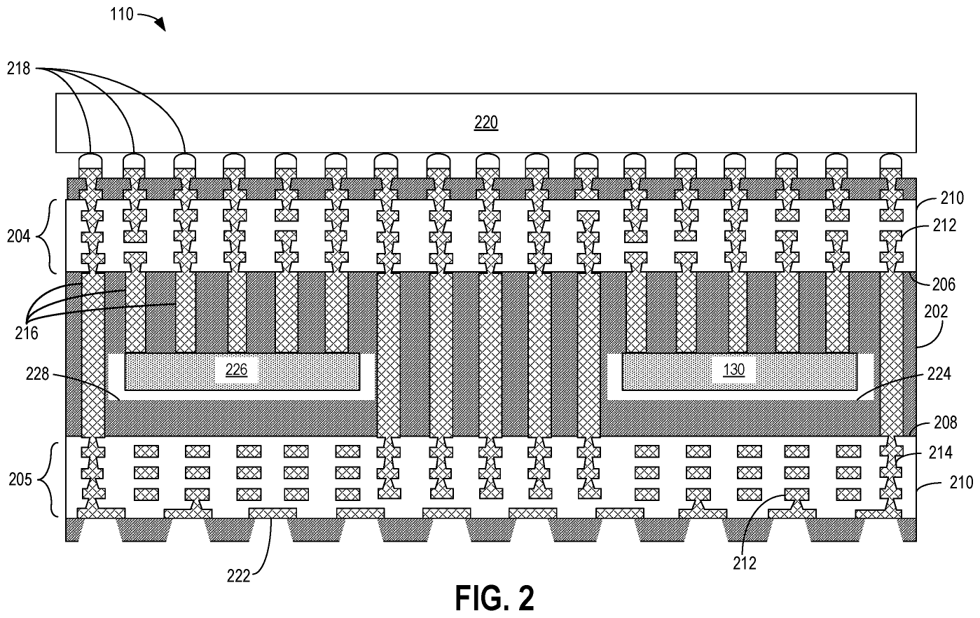

The example IC package 100 of FIG. 1 is a package that includes at least one MEMS die 130 (or any other embedded semiconductor die) integrated with and/or carried by the substrate 110. More particularly, in some examples, the substrate 110 includes a glass substrate, layer, panel, or core 202 (shown in FIG. 2) to which the MEMS die 130 is coupled. In various implementations, glass substrate 110 may comprise quartz, fused silica, and/or borosilicate glass. In some examples, the MEMS die 130 is distinct from the dies 106, 108 coupled to and/or carried by the substrate 110. Additionally or alternatively, at least one of the dies 106, 108 may be electrically coupled to electrodes of the MEMS die 130.

FIG. 2 is a cross-sectional view providing further detail for an example implementation of the example package substrate 110 of FIG. 1. The package substrate 110 of the illustrated example includes a glass substrate or core 202 between two separate build-up layers or regions 204, 205. In this example, the first build-up region 204 is provided on a first surface 206 of the glass core 202 and the second build-up region 205 is provided on a second surface 208 of the glass core 202 opposite the first surface 206. The build-up regions 204, 205 of the illustrated example are defined by an alternating pattern of insulation of dielectric layers 210 and patterned conductive (e.g., metal) layers 212. In some examples, at least one of the build-up regions 204, 205 may be omitted such that the glass core 202 defines an exterior surface of the package substrate 110.

The conductive layers 212 in the build-up regions 204, 205 (e.g., build-up layers) are patterned to define electrical routing or conductive traces that serve as signaling or transmission lines to transfer power and/or signals of information between two or more components (e.g., transistors, capacitors, resistors, backend layers, etc. and/or other circuitry) of an associated IC package (e.g., the IC package 100 of FIG. 1). Example electrically conductive (e.g., metal) vias 214 extend through the dielectric layers 210 to electrically couple different ones of the conductive layers 212 in the different build-up regions 204, 205. Further, as shown in FIG. 2, the glass core 202 of the illustrated example includes one or more through glass vias (TGVs) 216 (e.g., copper plated vias). At least some of the example TGVs 216 extend between the opposite surfaces 206, 208 of the glass core 202 to communicatively and/or electrically couple the conductive layers 212 and associated metal vias 214 within the build-up regions 204, 205 on either side of the glass core 202. Thus, in this example, the electrical routing or traces defined by the patterning of the conductive layers 212, the conductive vias 214, and the TGVs 216 collectively define electrical interconnects (e.g., the interconnects 124 of FIG. 1) through the substrate 110.

The example package substrate 110, shown in FIG. 1, includes the connectors 120 (e.g., solder balls, bumps, contact pads, pins, etc.) on the inner surface 122 of the substrate 110 to electrically couple the package substrate 110 to one or more semiconductor die (e.g., one of the dies 106, 108 of FIG. 1) and/or any other suitable component (e.g., an interposer). In the example of FIG. 2, the substrate 110 includes a first plurality of connectors 218 to electrically couple an example semiconductor die 220 (e.g., complementary metal oxide semiconductor (CMOS) die) to the build-up region 204. In some examples, the semiconductor die 220 shown in FIG. 2 corresponds to one of the dies 106, 108 shown in FIG. 1. Further, the example package substrate 110 includes a second plurality of connectors 222 (e.g., solder balls, bumps, contact pads, pins, etc.) to electrically couple the package substrate 110 to a printed circuit board (e.g., the circuit board 102 of FIG. 1), an interposer and/or any other substrate(s).

Although the glass core 202 of the example package substrate 110 is shown as a central core of the substrate 110, in some examples, the glass core 202 can be an interposer and/or any other layer of the package substrate 110. For example, the glass core 202 can be used in place of one or more of the dielectric layers 210 of the package substrate 110. In some examples, the package substrate 110 can include different material(s) including organic materials, silicon, and/or other conventional materials for fabricating package substrates. In some examples, the package substrate 110 includes an interconnect bridge—(e.g., the bridge 126 of FIG. 1).

High density substrate packaging techniques often use organic cores (e.g., an epoxy-based prepreg layer with a glass cloth) as a starting material in next-generation compute applications. These next-generation compute applications have an increased demand in scaling, which along with the proliferation of multichip architectures, specifies (e.g., dictates, requires, etc.) a reduction in warpage and thickness variation. As a result, the starting organic core material has become increasingly thicker in subsequent generation(s) to provide an effective lower coefficient of thermal expansion (CTE). The thicker starting organic core material bridges the gap (e.g., the difference, the delta) to the CTE of the silicon dies (e.g., the dies 106, 108 of FIG. 1) mounted on such substrates. However, increasing core thickness is not a universal solution, because some applications have a total core thickness restricted by customer demands (e.g., portable machines, mobile devices, etc.). In addition, the increased core thickness may be detrimental to the electrical performance of the product. By contrast and in accordance with the present disclosure, glass substrates (e.g., core 202) comprise at least one glass layer and do not comprise an epoxy-based prepreg layer with glass cloth.

Using glass as a starting core material (e.g., the glass core 202 of FIG. 2) has a mechanical benefit, an electrical benefit, and a design flexibility benefit over using traditional organic core materials (e.g., epoxy-based prepreg). Furthermore, it is possible to incorporate or integrate semiconductor dies directly into a package substrate adjacent a surface of the glass core. More particularly, in the illustrated example, of FIG. 2, the MEMS die 130 is embedded in the glass core 202. In other examples, the MEMS die 130 may be on a surface (e.g., the surface 206, the surface 208, etc.) of the glass core 202. In FIG. 2, the MEMS die 130 is positioned in a cavity 224 (e.g., recess) in the glass core 202. Further, the example package substrate 110 of FIG. 2 includes a second MEMS die 226 positioned in a second cavity 228 of the glass core 202. In FIG. 2, the two MEMS dies 130, 226 are shown, but the example package substrate 110 and/or the glass core 202 can be configured to support any number of MEMS dies (e.g., three, four, etc.) either in multiple cavities or within a single cavity. In this example, the MEMS dies 130, 226 are positioned between the surfaces 206, 208. Further, the first MEMS die 130 is spaced apart from the second MEMS die 226. As such, the first cavity 224 can be spaced apart from the second cavity 228. In some examples, the second MEMS die 226 and the associated cavity 228 are omitted.

In FIG. 2, the MEMS dies 130, 226 are spaced apart from the semiconductor die 220. For example, an example portion of the glass core 202 is positioned between at least one of the MEMS dies 130, 226 and the semiconductor die 220. However, at least one of the example MEMS dies 130, 226 can be electrically coupled to the semiconductor die 220 via at least one of the TGVs 216. In some examples, a first portion of the glass core 202 can separate the MEMS dies 130, 226 from the first build-up region 204 and a second portion of the glass core 202 can separate the MEMS dies 130, 226 from the second build-up region 205. In other words, an example portion of the glass core 202 can be positioned closer to the first build-up region 204 than at least one of the MEMS dies 130, 226 is to the first build-up region 204. Further, a second portion of the glass core 202 can be positioned closer to the second build-up region 205 than the at least one of the MEMS dies 130, 226 is to the second build-up region 205. At least one of the example MEMS dies 130, 226 can be electrically coupled to the first build-up region 204 via at least one of the TGVs 216 extending through the first portion of the glass core 202. Further, at least one of the MEMS dies 130, 226 can be electrically coupled to the second build-up region 205 via at least one of the TGVs 216 extending through the second portion of the glass core 202. In FIG. 2, the example MEMS dies 130, 226 are electrically coupled to the first build-up region 204 via at least one of the TGVs 216. In other examples, the MEMS dies 130, 226 can be electrically coupled to the first build-up region 204 via first ones of the TGVs 216 and to the second build-up region 204 via second ones of the TGVs 216. For example, the glass core 202 can include TGVs 216 extending from the cavities 224, 228 to the opposing surfaces 206, 208 of the glass core 202. In some examples, at least one of the TGVs 216 extends through the first and second portions of the glass core 202. In such examples, the second build-up region 205 is electrically coupled to the first build-up region 204 via the at least one of the TGVs 216.

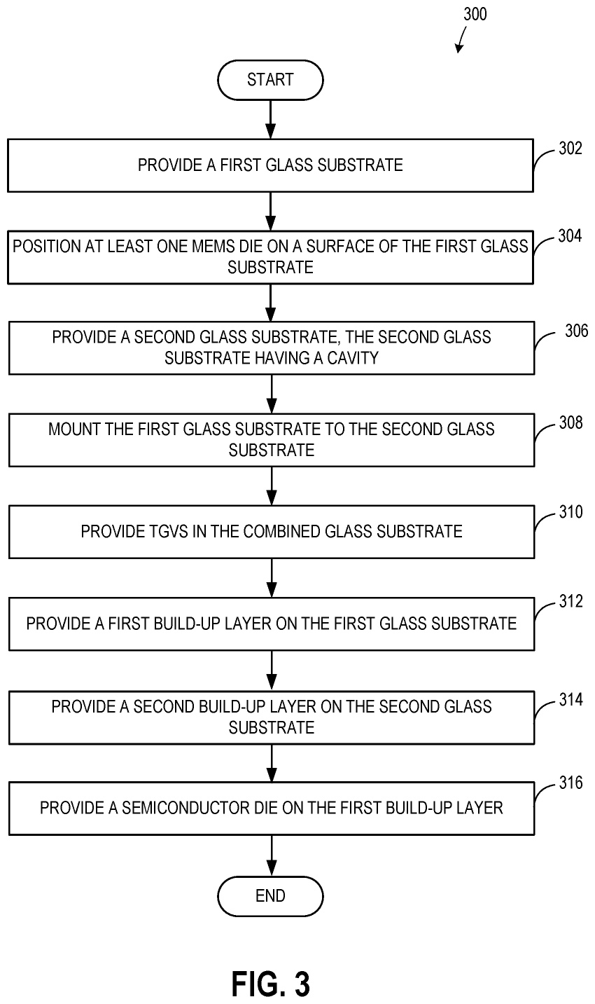

Additionally or alternatively, surfaces of the example MEMS dies 130, 226 are enclosed by the glass core 202. In some examples, the MEMS dies 130, 226 are sealed (e.g., at least partially sealed, hermetically sealed, etc.) by the glass core 202. For example, the cavities 224, 228 can be vacuumed sealed to seal the MEMS dies 130, 226. In some examples, at least one surface of the first MEMS die 130 and/or at least one surface of the second MEMS die 226 is in contact with the glass core 202. Example constructions of MEMS dies within a substrate containing a glass core are further detailed below in connection with FIGS. 3-13.

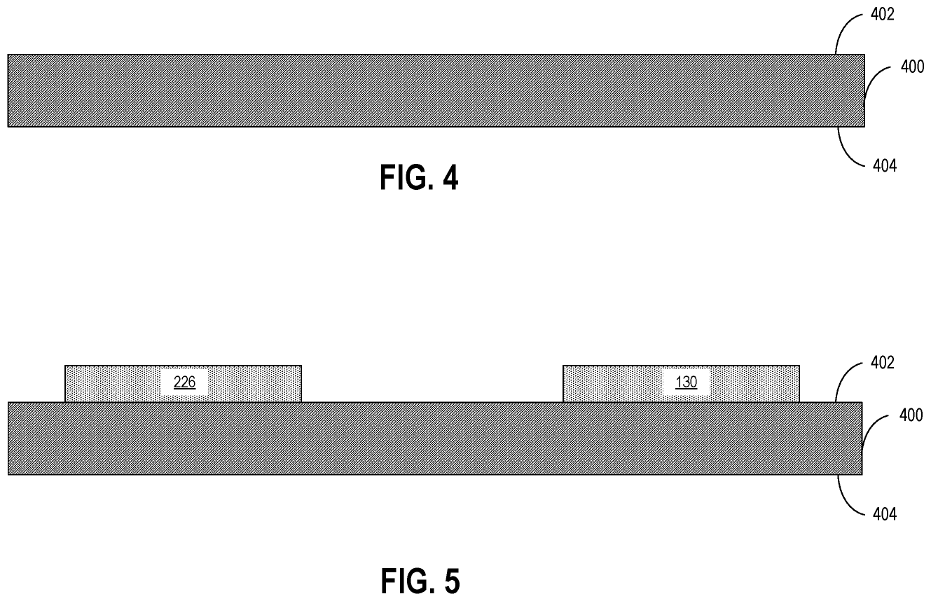

FIG. 3 is a flowchart representative of an example method to produce the example package substrate 110 of FIG. 2. FIGS. 4-11 represent the example package substrate 110 at various stages during the example process described in FIG. 3.

Turning to FIG. 3, the example process 300 begins at block 302 at which a first glass substrate 400 (e.g., a first portion of the glass core 202, a first piece of glass, etc.) is provided. As shown in FIG. 4, the first glass substrate 400 includes a first surface 402 opposite a second surface 404. In some examples, the first glass substrate 400 can include a cavity. For example, the first surface 402 can include a cavity.

At block 304, the example MEMS dies 130, 226 are positioned (e.g., disposed) on the first surface 402, as shown in FIG. 5. In some examples, at least one of the MEMS dies 130, 226 is positioned on the first surface 402. In this example, the first MEMS die 130 is spaced apart from the second MEMS die 226.

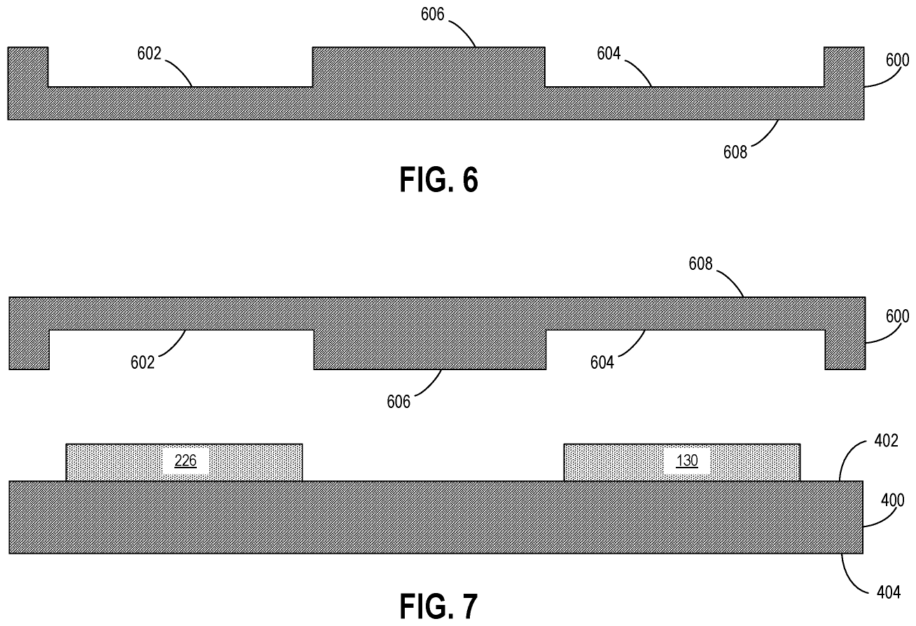

At block 306, a second glass substrate 600 is provided. As shown in FIG. 6, the second glass substrate 600 includes cavities 602, 604 positioned on a third surface 606. In FIG. 6, the third surface 606 is opposite a fourth surface 608. In some examples, the cavities 602, 604 are provided via any suitable etching and/or drilling process (e.g., laser drilling). In some examples, the cavities 602, 604 can remain void. In other examples, the cavities 602, 604 can be filled with any material to provide mechanical support, spacing, etc.

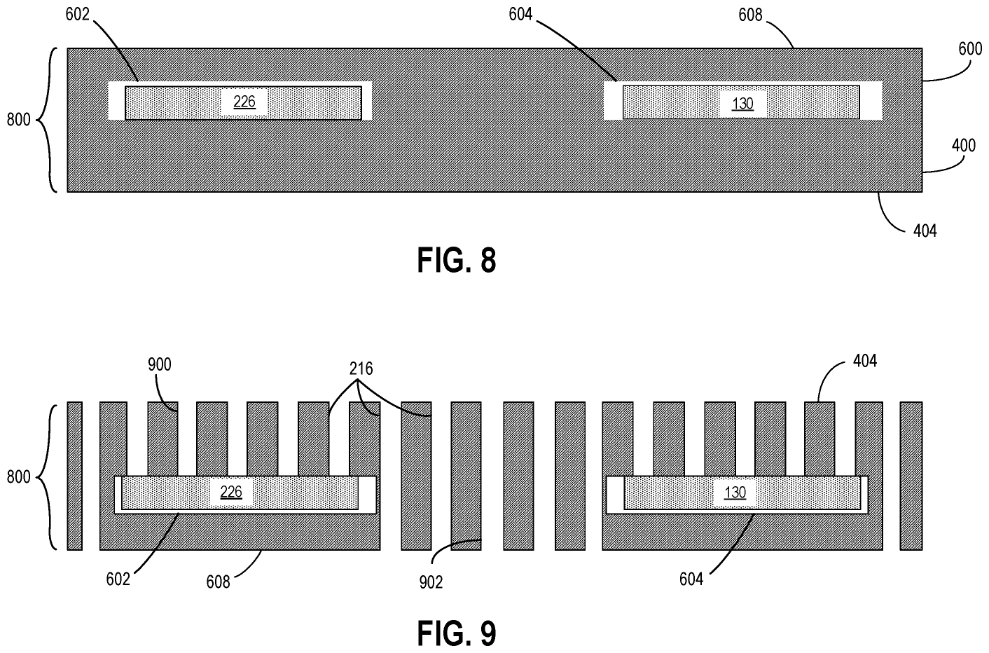

At block 308, the second glass substrate 600 is mounted to the first glass substrate 400, as shown in FIGS. 7 and 8. For example, the substrates 400, 600 are mounted (e.g., connected, coupled, fused, etc.) such that the third surface 606 of the second glass substrate 600 faces the first surface 402 of the first glass substrate 400. In some examples, the coupled glass substrates 400, 600 can be directly bonded or can be bonded via an intermediate bonding layer. The example MEMS dies 130, 226 are positioned between the first glass substrate 400 and the second glass substrate 600. In this example, the coupled ones of first and second substrates 400, 600 define a combined glass substrate 800 (e.g., monolithic core). As such, the second surface 404 is opposite the fourth surface 608 in the combined glass substrate 800 with the second and fourth surface 404, 608 shown in FIG. 8 corresponding to the respective first and second surfaces 206, 208 shown in FIG. 2. As shown most clearly with reference to FIG. 7, the MEMS dies 130, 226 are initially mounted to a planar surface (e.g., the first surface 402 of the first glass substrate 400) and then enclosed or surrounded by the cavities 602, 604 in the second glass substrate 600. In other examples, the MEMS dies 130, 226 may be initially inserted into the cavities 602, 604 of the second glass substrate 600 and then covered or enclosed by the planar surface of the first glass substrate 400. In other examples, both glass substrates 400, 600 may include cavities that are to be aligned to enclose the MEMS dies 130, 226 therein.

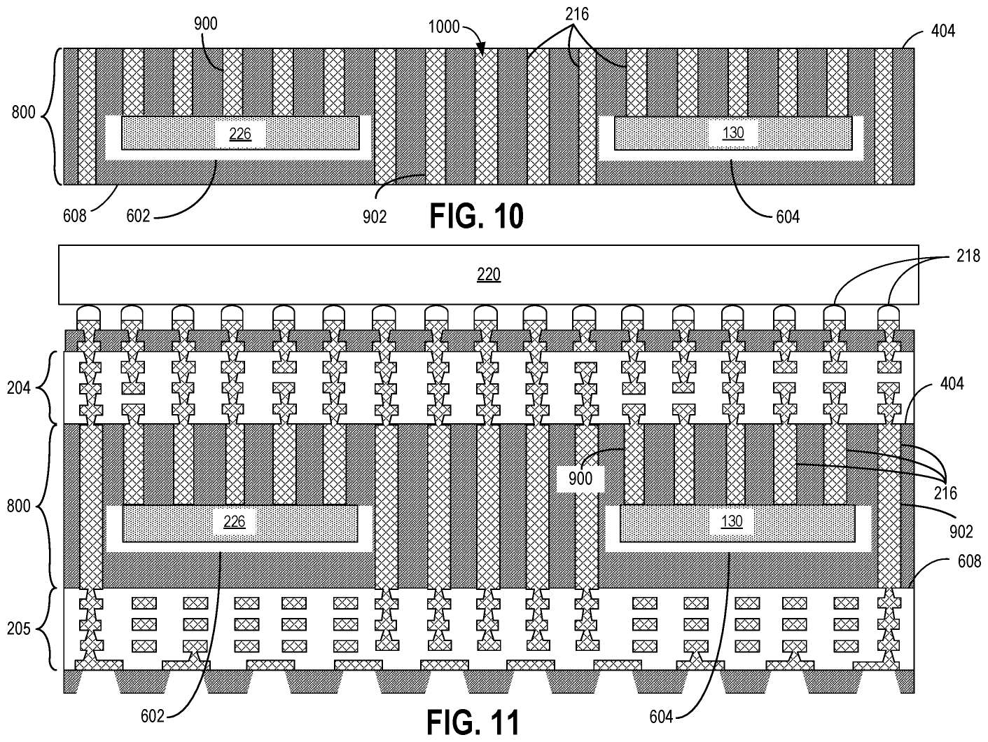

At block 310, the TGVs 216 are provided (e.g., etched) in the combined glass substrate 800, as shown in FIGS. 9 and 10 (in which the assembly has been flipped or inverted relative to the orientation shown in FIGS. 4-8). In some examples, at least one of the TGVs 216 extend from the second surface 404 to at least one of the MEMS dies 130, 226. For example, a first TGV 900 extends from the surface 404 to the MEMS die 226 (e.g., a surface of the MEMS die 226). In other examples, at least one of the TGVs 216 extend from the second surface 404 to the fourth surface 608. For example, a second TGV 902 extends from the surface 404 to the surface 608. In FIG. 10, the example TGVs 216 can be plated with a metallic material 1000 (e.g., copper). In some examples, the TGVs 216 are provided using any suitable etching and/or drilling process (e.g., laser drilling). In some examples, some or all of the TGVs 216 are provided in the combined glass substrate 800 prior to the combining of the first and second glass substrates 400, 600. In some examples, some or all of the TGVs 216 are provided in the glass substrates 400, 600 prior to attaching the MEMS dies 130, 226.

At block 312, the first build-up layer 204 is provided on the combined glass substrate 800, as shown in FIG. 11. In particular, the first build-up layer 204 is provided on the second surface 404 of the first glass substrate 400 and/or the glass substrate 800. In the example of FIG. 11, the first build-up layer 204 includes connectors 218. Further, the build-up layer 204 is electrically coupled to the MEMS dies 130, 226 via the TGVs 216 (e.g., the TGV 900).

At block 314, the second build-up layer 205 is provided on the combined glass substrate 800, as shown in FIG. 11. In particular, the second build-up layer 205 is provided on the fourth surface 608 of the second glass substrate 600 and/or the glass substrate 800. In the example of FIG. 11, the second build-up layer 205 is electrically coupled to the first build-up layer 204 via the TGVs 216. For example, at least the TGV 902 electrically couples the second build-up layer 205 to the first build-up layer 204.

At block 316, the semiconductor die 220 is provided on the first build-up layer 204, as shown in FIG. 11. The example semiconductor die 220 is electrically coupled to the first build-up layer 204 via the connectors 218. Further, the example semiconductor die 220 is electrically coupled to the MEMS dies 130, 226 via the TGVs 216 and the first build-up layer 204. For example, the semiconductor die 220 is electrically coupled to the MEMS die 130 via the first build-up layer 204 and the TGV 900.

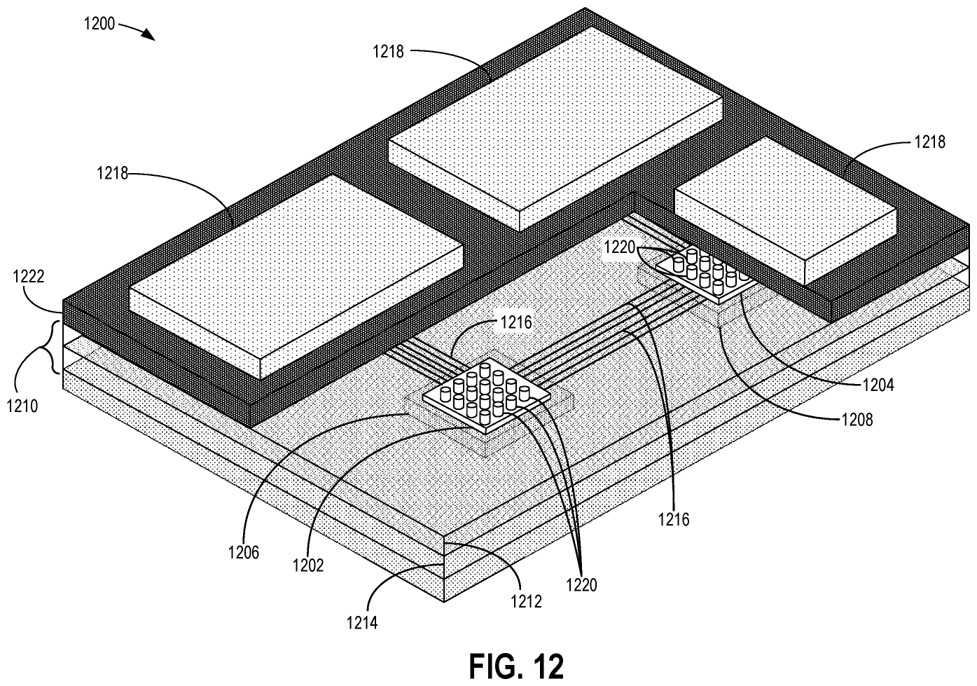

FIG. 12 is a cutaway view of another example package substrate 1200 constructed in accordance with teachings disclosed herein. FIG. 12 is similar to the example package substrate 110 of FIG. 2 in that the example package substrate 1200 of FIG. 12 includes two MEMS dies 1202, 1204 embedded or positioned within cavities 1206, 1208 of a glass core 1210 corresponding to two glass substrates 1212, 1214 attached together as shown and described in connection with FIGS. 4-8. However, unlike the example package substrate 110 of FIG. 2, the example package substrate 1200 of FIG. 12 includes interconnects 1216 extending through the glass core 1210 between example MEMS dies 1202, 1204. In FIG. 12, the two MEMS dies 1202, 1204 are shown, but the example package substrate 1200 and/or the glass core 1210 can be configured to support any number of MEMS dies (e.g., three, four, etc.). In some examples, the MEMS dies 1202, 1204 can be photonic integrated circuits (PICs) (e.g., optical switch dies, micro mirror devices for photonic communication, etc.). In such examples, the interconnects 1216 can include waveguides to optically couple the PICs. In some examples, the PICS and the waveguides can define an example photonic communication network within the package substrate 1200 for cross die (e.g., between MEMS dies 1202, 1204) communication. In other examples, the MEMS dies 1202, 1204 can include at least one of an oscillator, an actuator, a temperature sensor, a pressure sensor, or an inertial sensor (e.g., an accelerometer). As such, at least one of the MEMS dies 1202, 1204 can detect a movement associated with the package substrate 1200, a temperature associated with the package substrate 1200, a pressure associated with the package substrate 1200, etc.

The example package substrate 1200 includes (e.g., supports) system-on-a-chip (SOC) dies 1218. In the example of FIG. 12, the SOC dies 1218 can be electrically coupled to the MEMS dies 1202, 1204 via example TGVs 1220 extending through the glass core 1210. Further, the example SOC dies 1218 may be disposed on a build-up layer 1222. The example build-up layer 1222 can separate the SOC dies 1218 from the glass core 1210 and, subsequently, the MEMS dies 1202, 1204.

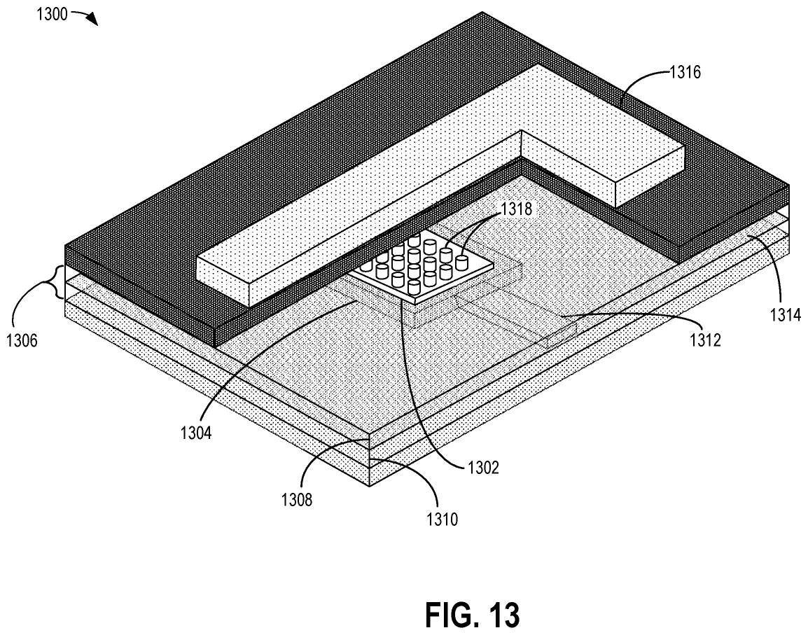

FIG. 13 illustrates another example package substrate 1300 constructed in accordance with teachings disclosed herein. The example package substrate 1300 of FIG. 13 is similar to the example package substrates 110, 1200 of FIGS. 2 and/or 12 in that the example package substrate 1300 of FIG. 13 includes a MEMS die 1302 embedded or positioned within a cavity 1304 of a glass core 1306 corresponding to two glass substrates 1308, 1310 attached together as shown and described in connection with FIGS. 4-8. However, unlike the example package substrates 110, 1200 of FIGS. 2 and/or 12, the example package substrate 1300 of FIG. 13 includes an example channel 1312 (e.g., aperture, groove, opening, etc.) extending from the cavity 1304 containing the example MEMS die 1302 to (e.g., through) at least one surface 1314 of the example glass core 1306. In some examples, the channel 1312 can extend from the MEMS die 1302 to an outer surface (e.g., a perimeter) of the package substrate 1300.

In some examples, the MEMS die 1302 includes a sensor to detect (e.g., sense, interact with, etc.) a characteristic of an environment of the package substrate 1300 via the channel 1312. As such, the example MEMS die 1302 can obtain data associated with surroundings of the package substrate 1300. In this example, the MEMS die 1302 may also be electrically coupled to an example SOC die 1316 (e.g., via example TGVs 1318 through the glass core 1306).

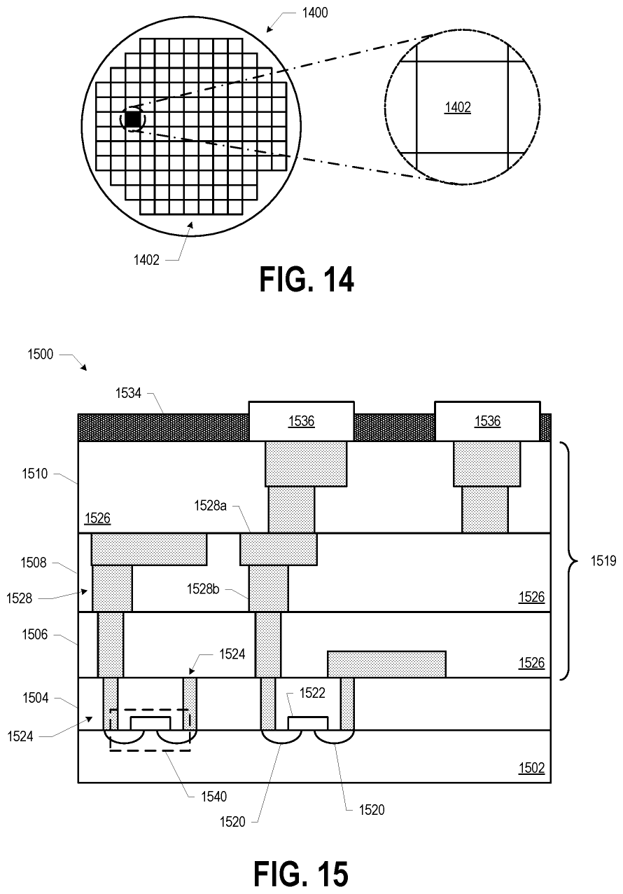

The example package substrates 110, 1200, 1300 disclosed herein may be included in any suitable electronic component. FIGS. 14-16 illustrate various examples of apparatus that may include or be included in the package substrates 110, 1200, 1300 disclosed herein.

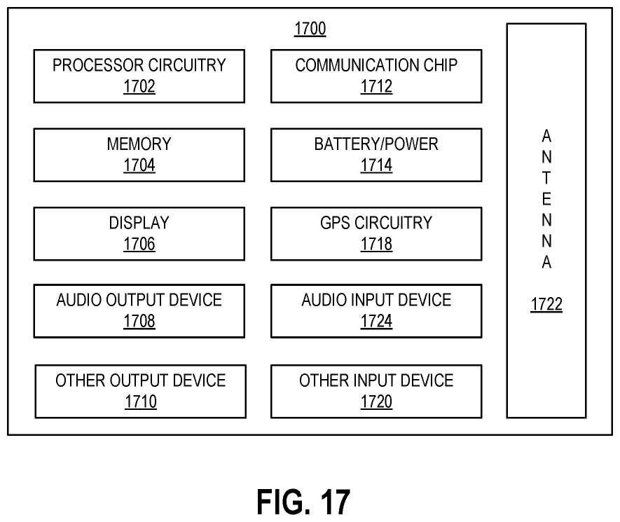

FIG. 14 is a top view of an example wafer 1400 and dies 1402 that may be included in the package substrates 110, 1200, 1300 (e.g., as any suitable ones of the dies 106, 108, 220 and/or the MEMS dies 130, 226, 1202, 1204, 1302). The wafer 1400 may be composed of semiconductor material and may include one or more dies 1402 having circuitry. Some or all of the dies 1402 may be a repeating unit of a semiconductor product. After the fabrication of the semiconductor product is complete, the wafer 1400 may undergo a singulation process in which the dies 1402 are separated from one another to provide discrete “chips.” The die 1402 may include one or more transistors (e.g., some of the transistors 1540 of FIG. 15, discussed below), supporting circuitry to route electrical signals to the transistors, passive components (e.g., traces, resistors, capacitors, inductors, and/or other circuitry), and/or any other components. In some examples, the die 1402 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1402. For example, a memory array formed by multiple memory circuits may be formed on a same die 1402 as programmable circuitry (e.g., the processor circuitry 1702 of FIG. 17) or other logic circuitry. Such memory may store information for use by the programmable circuitry. The example package substrates 110, 1200, 1300 disclosed herein may be manufactured using a die-to-wafer assembly technique in which some dies 106, 108 are attached to a wafer 1400 that include others of the dies 106, 108, and the wafer 1400 is subsequently singulated.

FIG. 15 is a cross-sectional side view of an example IC device 1500 that may be included in the example package substrates 110, 1200, 1300 (e.g., in any one of the dies 106, 108, 220 and/or the MEMS dies 130, 226, 1202, 1204, 1302). One or more of the IC devices 1500 may be included in one or more dies 1402 (FIG. 14). The IC device 1500 may be formed on an example die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some examples, the die substrate 1502 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an IC device 1500 may be used. The die substrate 1502 may be part of a singulated die (e.g., the dies 1402 of FIG. 14) or a wafer (e.g., the wafer 1400 of FIG. 14).

The IC device 1500 may include one or more example device layers 1504 disposed on or above the die substrate 1502. The device layer 1504 may include features of one or more example transistors 1540 (e.g., metal oxide semiconductor field-effect transistors (MOSFETs)) formed on the die substrate 1502. The device layer 1504 may include, for example, one or more example source and/or drain (S/D) regions 1520, an example gate 1522 to control current flow between the S/D regions 1520, and one or more example S/D contacts 1524 to route electrical signals to/from the S/D regions 1520. The transistors 1540 may include additional features not depicted for the sake of clarity such as, for example, device isolation regions, gate contacts, and the like. The transistors 1540 are not limited to the type and configuration depicted in FIG. 15 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1540 may include an example gate 1522 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1540 along the source-channel-drain direction, the gate electrode may include a U-shaped structure that includes a bottom portion substantially parallel to the surface of the die substrate 1502 and two sidewall portions that are substantially perpendicular to the top surface of the die substrate 1502. In other examples, at least one of the metal layers that form the gate electrode may be a planar layer that is substantially parallel to the top surface of the die substrate 1502 and does not include sidewall portions substantially perpendicular to the top surface of the die substrate 1502. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of respective ones of the transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes the dopants to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1520 may be formed using one or more alternate semiconductor materials such as germanium or a group III-V material or alloy. In further examples, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more example interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with example interconnect structures 1528 of the interconnect layers 1506-1510. The one or more interconnect layers 1506-1510 may form an example metallization stack (also referred to as an “ILD stack”) 1519 of the IC device 1500.

The interconnect structures 1528 may be arranged within the interconnect layers 1506-1510 to route electrical signals according to a wide variety of designs (in particular, the arrangement is not limited to the particular configuration of interconnect structures 1528 depicted in FIG. 15). Although a particular number of interconnect layers 1506-1510 is depicted in FIG. 15, examples of the present disclosure include IC devices having more or fewer interconnect layers than depicted.

In some examples, the interconnect structures 1528 may include example lines 1528a and/or example vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page from the perspective of FIG. 15. The vias 1528b may be arranged to route electrical signals in a direction of a plane that is substantially perpendicular to the surface of the die substrate 1502 upon which the device layer 1504 is formed. In some examples, the vias 1528b may electrically couple lines 1528a of different interconnect layers 1506-1510 together.

The interconnect layers 1506-1510 may include an example dielectric material 1526 disposed between the interconnect structures 1528, as shown in FIG. 15. In some examples, the dielectric material 1526 disposed between the interconnect structures 1528 in different ones of the interconnect layers 1506-1510 may have different compositions. In other examples, the composition of the dielectric material 1526 between different interconnect layers 1506-1510 may be the same.

A first interconnect layer 1506 (referred to as Metal 1 or “M1”) may be formed directly on the device layer 1504. In some examples, the first interconnect layer 1506 may include lines 1528a and/or vias 1528b, as shown. The lines 1528a of the first interconnect layer 1506 may be coupled with contacts (e.g., the S/D contacts 1524) of the device layer 1504.

A second interconnect layer 1508 (referred to as Metal 2 or “M2”) may be formed directly on the first interconnect layer 1506. In some examples, the second interconnect layer 1508 may include vias 1528b to couple the lines 1528a of the second interconnect layer 1508 with the lines 1528a of the first interconnect layer 1506. Although the lines 1528a and the vias 1528b are structurally delineated with a line within each interconnect layer (e.g., within the second interconnect layer 1508) for the sake of clarity, the lines 1528a and the vias 1528b may be structurally and/or materially contiguous (e.g., simultaneously filled during a dual-damascene process) in some examples.

A third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 and/or the first interconnect layer 1506. In some examples, the interconnect layers that are “higher up” in the metallization stack 1519 in the IC device 1500 (i.e., further away from the device layer 1504) may be thicker.

The IC device 1500 may include an example solder resist material 1534 (e.g., polyimide or similar material) and one or more example conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to other external devices. For example, solder bonds may be formed on the one or more conductive contacts 1536 to mechanically and/or electrically couple a chip including the IC device 1500 with another component (e.g., a circuit board). The IC device 1500 may include additional or alternate structures to route the electrical signals from the interconnect layers 1506-1510; for example, the conductive contacts 1536 may include other analogous features (e.g., posts) that route the electrical signals to external components.

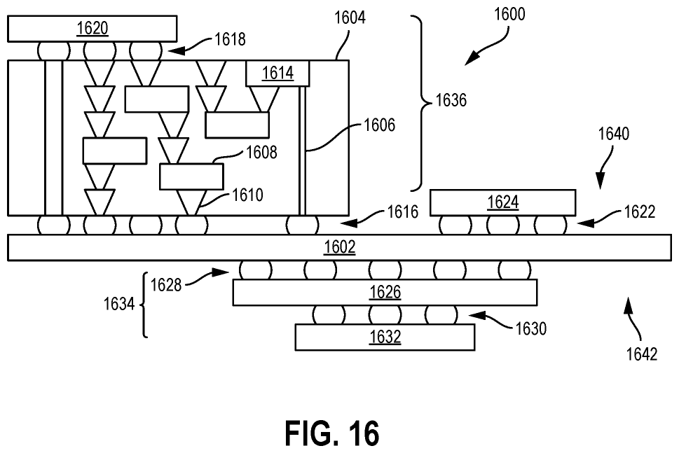

FIG. 16 is a cross-sectional side view of an example IC device assembly 1600 that may include the package substrates 110, 1200, 1300 disclosed herein. In some examples, the IC device assembly corresponds to and/or includes the example IC package 100 of FIG. 1. The IC device assembly 1600 includes a number of components disposed on an example circuit board 1602 (which may be, for example, a motherboard). The IC device assembly 1600 includes components disposed on an example first face 1640 of the circuit board 1602 and an example opposing second face 1642 of the circuit board 1602. Any of the IC packages discussed herein with reference to the IC device assembly 1600 may take the form of and/or include one or more of the example package substrates 110, 1200, 1300.

In some examples, the circuit board 1602 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1602. In other examples, the circuit board 1602 may be a non-PCB substrate. In some examples, the circuit board 1602 may be, for example, the circuit board 102 of FIG. 1.

The IC device assembly 1600 illustrated in FIG. 16 includes an example package-on-interposer structure 1636 coupled to the first face 1640 of the circuit board 1602 by example coupling components 1616. The coupling components 1616 may electrically and mechanically couple the package-on-interposer structure 1636 to the circuit board 1602, and may include solder balls (as shown in FIG. 16), male and female portions of a socket, an adhesive, an underfill material, and/or any other suitable electrical, chemical, and/or mechanical coupling structure.

The package-on-interposer structure 1636 may include an example IC package 1620 coupled to an example interposer 1604 by example coupling components 1618. The coupling components 1618 may take any suitable form for the application, such as the forms discussed above with reference to the coupling components 1616. Although a single IC package 1620 is shown in FIG. 16, multiple IC packages may be coupled to the interposer 1604. Additionally or alternatively, in some examples, additional interposers may be coupled to the interposer 1604. The interposer 1604 may provide an intervening substrate used to bridge the circuit board 1602 and the IC package 1620. The IC package 1620 may be or include, for example, a die (the die 1402 of FIG. 14), an IC device (e.g., the IC device 1500 of FIG. 15), and/or any other suitable component(s). Generally, the interposer 1604 may spread a connection to a wider pitch or reroute a connection to a different connection. For example, the interposer 1604 may couple the IC package 1620 (e.g., a die) to a set of BGA conductive contacts of the coupling components 1616 for coupling to the circuit board 1602. In the example illustrated in FIG. 16, the IC package 1620 and the circuit board 1602 are attached to opposing sides of the interposer 1604. In other examples, the IC package 1620 and the circuit board 1602 may be attached to a same side of the interposer 1604. In some examples, three or more components may be interconnected by way of the interposer 1604.

In some examples, the interposer 1604 may be formed as a PCB, including multiple metal layers separated from one another by layers of dielectric material and interconnected by electrically conductive vias. In some examples, the interposer 1604 may be formed of an epoxy resin, a fiberglass-reinforced epoxy resin, an epoxy resin with inorganic fillers, a ceramic material, or a polymer material such as polyimide. In some examples, the interposer 1604 may be formed of alternate rigid or flexible materials that may include the same materials described above for use in a semiconductor substrate, such as silicon, germanium, and other group III-V and group IV materials. The interposer 1604 may include example metal interconnects 1608 and example vias 1610, including but not limited to example through-silicon vias (TSVs) 1606. The interposer 1604 may further include example embedded devices 1614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1604. The package-on-interposer structure 1636 may take the form of any of the package-on-interposer structures known in the art.

The IC device assembly 1600 may include an example IC package 1624 coupled to the first face 1640 of the circuit board 1602 by example coupling components 1622. The coupling components 1622 may take the form of any of the examples discussed above with reference to the coupling components 1616, and the IC package 1624 may take the form of any of the examples discussed above with reference to the IC package 1620.

The IC device assembly 1600 illustrated in FIG. 16 includes an example package-on-package structure 1634 coupled to the second face 1642 of the circuit board 1602 by coupling components 1628. The package-on-package structure 1634 may include a first example IC package 1626 and a second example IC package 1632 coupled together by example coupling components 1630 such that the first IC package 1626 is disposed between the circuit board 1602 and the second IC package 1632. The coupling components 1628, 1630 may take the form of any of the examples of the coupling components 1616 discussed above, and the IC packages 1626, 1632 may take the form of any of the examples of the IC package 1620 discussed above.

FIG. 17 is a block diagram of an example electrical device 1700 that may include one or more of the example package substrates 110, 1200, 1300. For example, any suitable ones of the components of the electrical device 1700 may include one or more of the device assemblies 1600, IC devices 1500, or dies 1402 disclosed herein, and may be arranged in and/or associated with the example package substrates 110, 1200, 1300. A number of components are illustrated in FIG. 17 as included in the electrical device 1700, but any one or more of these components may be omitted or duplicated, as suitable for the application. In some examples, some or all of the components included in the electrical device 1700 may be attached to one or more motherboards. In some examples, some or all of these components are fabricated onto a single SoC die.

Additionally, in some examples, the electrical device 1700 may not include one or more of the components illustrated in FIG. 17, but the electrical device 1700 may include interface circuitry for coupling to the one or more components. For example, the electrical device 1700 may not include an example display 1706, but may include display interface circuitry (e.g., a connector and driver circuitry) to which the display 1706 may be coupled. In some examples, the electrical device 1700 may not include an example audio input device 1724 (e.g., microphone) or an example audio output device 1708 (e.g., a speaker, a headset, earbuds, etc.), but may include audio input or output device interface circuitry (e.g., connectors and supporting circuitry) to which the audio input device 1724 or the audio output device 1708 may be coupled.

The electrical device 1700 may include example programmable or processor circuitry 1702 (e.g., one or more processing devices). The processor circuitry 1702 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1700 may include an example memory 1704, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1704 may include memory that shares a die with the programmable circuitry 1702. This memory may be used as cache memory and may include embedded dynamic random access memory (eDRAM) or spin transfer torque magnetic random access memory (STT-MRAM).

In some examples, the electrical device 1700 may include an example communication chip 1712 (e.g., one or more communication chips). For example, the communication chip 1712 may be configured for managing wireless communications for the transfer of data to and from the electrical device 1700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1712 may operate in accordance with other wireless protocols in other examples. The electrical device 1700 may include an example antenna 1722 to facilitate wireless communications and/or to receive other wireless communications (such as AM or FM radio transmissions).

In some examples, the communication chip 1712 may manage wired communications, such as electrical, optical, or any other suitable communication protocols (e.g., the Ethernet). As noted above, the communication chip 1712 may include multiple communication chips. For instance, a first communication chip 1712 may be dedicated to shorter-range wireless communications such as Wi-Fi or Bluetooth, and a second communication chip 1712 may be dedicated to longer-range wireless communications such as global positioning system (GPS), EDGE, GPRS, CDMA, WiMAX, LTE, EV-DO, or others. In some examples, a first communication chip 1712 may be dedicated to wireless communications, and a second communication chip 1712 may be dedicated to wired communications.

The electrical device 1700 may include example battery/power circuitry 1714. The battery/power circuitry 1714 may include one or more energy storage devices (e.g., batteries or capacitors) and/or circuitry for coupling components of the electrical device 1700 to an energy source separate from the electrical device 1700 (e.g., AC line power).

The electrical device 1700 may include the display 1706 (or corresponding interface circuitry, as discussed above). The display 1706 may include any visual indicators, such as a heads-up display, a computer monitor, a projector, a touchscreen display, a liquid crystal display (LCD), a light-emitting diode display, or a flat panel display.

The electrical device 1700 may include the audio output device 1708 (or corresponding interface circuitry, as discussed above). The audio output device 1708 may include any device that generates an audible indicator, such as speakers, headsets, or earbuds.

The electrical device 1700 may include the audio input device 1724 (or corresponding interface circuitry, as discussed above). The audio input device 1724 may include any device that generates a signal representative of a sound, such as microphones, microphone arrays, or digital instruments (e.g., instruments having a musical instrument digital interface (MIDI) output).

The electrical device 1700 may include example GPS circuitry 1718. The GPS circuitry 1718 may be in communication with a satellite-based system and may receive a location of the electrical device 1700, as known in the art.

The electrical device 1700 may include any other example output device 1710 (or corresponding interface circuitry, as discussed above). Examples of the other output device 1710 may include an audio codec, a video codec, a printer, a wired or wireless transmitter for providing information to other devices, and/or an additional storage device.

The electrical device 1700 may include any other example input device 1720 (or corresponding interface circuitry, as discussed above). Examples of the other input device 1720 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1700 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1700 may be any other electronic device that processes data.

From the foregoing, it will be appreciated that example systems, methods, apparatus, and articles of manufacture have been disclosed that utilize at least one glass core to embed one or more MEMS dies in a package substrate of an IC package. Examples disclosed herein employ a glass core to provide mechanical strength to an example IC package and reduce substrate warpage. Further, in examples disclosed herein, the glass core enables higher density electrical routing through an example IC package. As such, examples disclosed increase electrical performance of an example IC package.

Example 1 includes an integrated circuit (IC) package comprising a package substrate including a glass core, and a micro electromechanical system (MEMS) die positioned in a cavity of the glass core.

Example 2 includes the IC package of example 1, wherein the glass core has opposing first and second surfaces, the MEMS die between the opposing first and second surfaces.

Example 3 includes the IC package of example 1, wherein the glass core includes a first portion of glass and a second portion of glass coupled to the first portion of the glass, the MEMS die positioned between the first portion and the second portion, at least one of the first portion or the second portion including the cavity.

Example 4 includes the IC package of example 1, wherein surfaces of the MEMS die are enclosed by the glass core.

Example 5 includes the IC package of example 1, wherein the MEMS die is hermetically sealed within the glass core.

Example 6 includes the IC package of example 1, wherein the MEMS die includes at least one of an oscillator, an actuator, an inertial sensor, a pressure sensor, a temperature sensor, or a photonic integrated circuit.

Example 7 includes the IC package of example 1, further including a semiconductor die supported on the package substrate, a portion of the glass core is between the MEMS die and the semiconductor die.

Example 8 includes the IC package of example 1, wherein the MEMS die is a first MEMS die, further including a second MEMS die disposed in the cavity.

Example 9 includes the IC package of example 1, wherein the package substrate includes a build-up region on a first surface of the glass core, the first surface opposite a second surface of the glass core, a portion of the glass core between the build-up region and the MEMS die, the portion of the glass core including a through glass via (TGV) extending therethrough, the TGV to electrically couple the MEMS die to the build-up region.

Example 10 includes the IC package of example 9, wherein the build-up region is a first build-up region, the portion is a first portion, and the TGV is a first TGV, the glass core including a second build-up region on the second surface, the glass core including a second portion between the MEMS die and the second build-up region, the glass core including a second TGV extending through the first portion and the second portion, the second TGV to electrically couple the first build-up region to the second build-up region.

Example 11 includes the package of example 10, wherein the MEMS die is electrically coupled to the second build-up region via a third TGV, the third TGV extending through the second portion.

Example 12 includes the IC package of example 1, wherein the cavity is a first cavity and the MEMS die is a first MEMS die, further including a second MEMS die positioned in a second cavity of the glass core, the first and second cavities spaced apart within the glass core.

Example 13 includes the IC package of example 12, further including an interconnect extending between the first and second cavities to electrically couple the first MEMS die to the second MEMS die.

Example 14 includes the IC package of example 12, further including a waveguide extending through the glass core between the first MEMS die and the second MEMS die, the waveguide to optically couple the first MEMS die to the second MEMS die.

Example 15 includes the IC package of example 1, wherein the glass core includes a channel extending from the cavity to an outer surface of the IC package.

Example 16 includes the IC package of example 15, wherein the MEMS die includes a sensor, the sensor to detect a characteristic of an environment of the IC package via the channel.

Example 17 includes a package substrate for an integrated circuit (IC) package, the package substrate comprising a glass core having a first surface and a second surface opposite the first surface, a first build-up region on the first surface of the glass core, a second build-up region on the second surface of the glass core, and a micro electromechanical system (MEMS) die between the first build-up region and the second build-up region, the glass core closer to the first build-up region than the MEMS die is to the first build-up region, the glass core closer to the second build-up region than the MEMS die is to the second build-up region.

Example 18 includes the package substrate of example 17, wherein the glass core includes a first piece of glass and a second piece of glass, the MEMS die disposed on a surface of the first piece, the first piece to interface with the second piece.

Example 19 includes the package substrate of example 17, wherein at least one surface of the MEMS die is in contact with the glass core.

Example 20 includes the package substrate of example 17, wherein the MEMS die detects at least one of a pressure associated with the IC package, a temperature associated with the IC package, or a movement associated with the IC package.

Example 21 includes the package substrate of example 17, wherein the MEMS die is to obtain data associated with surroundings of the package substrate.

Example 22 includes a method comprising providing a first glass substrate, positioning a micro electromechanical system (MEMS) die on a surface of the first glass substrate, and mounting a second glass substrate to the first glass substrate, the MEMS die to be between the first and second glass substrates.

Example 23 includes the method of example 22, wherein the MEMS die is a first MEMS die, further including positioning a second MEMS die on the surface of the first glass substrate, the second MEMS die spaced apart from the first MEMS die.

Example 24 includes the method of example 22, wherein the surface is a first surface, the method further including providing a through glass via (TGV) extending through the first glass substrate between the first surface and a second surface of the first glass substrate, the second surface facing away from the first surface of the first glass substrate, and providing a build-up layer on the second surface of the first glass substrate, the TGV to electrically couple the MEMS die to the build-up layer.

Example 25 includes the method of example 24, wherein the build-up layer is a first build-up layer and the TGV is a first TGV, further including providing a second TGV extending through the first glass substrate and the second glass substrate between the second surface and a third surface of the second glass substrate, the third surface facing away from the second surface of the first glass substrate, and providing a second build-up layer on the third surface of the second glass substrate, the second TGV to electrically couple the first build-up layer to the second build-up layer.

Example 26 includes the method of example 25, further including mounting a semiconductor die on at least one of the first build-up layer or the second build-up layer.

Example 27 includes an apparatus comprising a first glass substrate, a micro electromechanical system (MEMS) die positioned on a surface of the first glass substrate, and a second glass substrate mounted to the first glass substrate, the MEMS die to be between the first and second glass substrates.

Example 28 includes the apparatus of example 27, wherein the MEMS die is a first MEMS die, further including a second MEMS die positioned on the surface of the first glass substrate, the second MEMS die spaced apart from the first MEMS die.

Example 29 includes the apparatus of example 27, wherein the surface is a first surface, further including a through glass via (TGV) extending through the first glass substrate between the first surface and a second surface of the first glass substrate, the second surface facing away from the first surface of the first glass substrate, and a build-up layer positioned on the second surface of the first glass substrate, the TGV to electrically couple the MEMS die to the build-up layer.

Example 30 includes the apparatus of example 29, wherein the build-up layer is a first build-up layer and the TGV is a first TGV, further including a second TGV extending through the first glass substrate and the second glass substrate between the second surface and a third surface of the second glass substrate, the third surface facing away from the second surface of the first glass substrate, and a second build-up layer positioned on the third surface of the second glass substrate, the second TGV to electrically couple the first build-up layer to the second build-up layer.

Example 31 includes the apparatus of example 30, further including a semiconductor die mounted on at least one of the first build-up layer or the second build-up layer.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An integrated circuit (IC) package comprising:
a package substrate including a glass core; and
a micro electromechanical system (MEMS) die positioned in a cavity of the glass core.

2. The IC package of claim 1, wherein the glass core has opposing first and second surfaces, the MEMS die between the opposing first and second surfaces.

3. The IC package of claim 1, wherein the glass core includes a first portion of glass and a second portion of glass coupled to the first portion of the glass, the MEMS die positioned between the first portion and the second portion, at least one of the first portion or the second portion including the cavity.

4. The IC package of claim 1, wherein surfaces of the MEMS die are enclosed by the glass core.

5. The IC package of claim 1, wherein the MEMS die is hermetically sealed within the glass core.

6. The IC package of claim 1, wherein the MEMS die includes at least one of an oscillator, an actuator, an inertial sensor, a pressure sensor, a temperature sensor, or a photonic integrated circuit.

7. The IC package of claim 1, further including a semiconductor die supported on the package substrate, a portion of the glass core is between the MEMS die and the semiconductor die.

8. (canceled)

9. The IC package of claim 1, wherein the package substrate includes a build-up region on a first surface of the glass core, the first surface opposite a second surface of the glass core, a portion of the glass core between the build-up region and the MEMS die, the portion of the glass core including a through glass via (TGV) extending therethrough, the TGV to electrically couple the MEMS die to the build-up region.

10. The IC package of claim 9, wherein the build-up region is a first build-up region, the portion is a first portion, and the TGV is a first TGV, the glass core including a second build-up region on the second surface, the glass core including a second portion between the MEMS die and the second build-up region, the glass core including a second TGV extending through the first portion and the second portion, the second TGV to electrically couple the first build-up region to the second build-up region.

11. (canceled)

12. The IC package of claim 1, wherein the cavity is a first cavity and the MEMS die is a first MEMS die, further including a second MEMS die positioned in a second cavity of the glass core, the first and second cavities spaced apart within the glass core.

13. The IC package of claim 12, further including an interconnect extending between the first and second cavities to electrically couple the first MEMS die to the second MEMS die.

14. The IC package of claim 12, further including a waveguide extending through the glass core between the first MEMS die and the second MEMS die, the waveguide to optically couple the first MEMS die to the second MEMS die.

15. The IC package of claim 1, wherein the glass core includes a channel extending from the cavity to an outer surface of the IC package.

16. The IC package of claim 15, wherein the MEMS die includes a sensor, the sensor to detect a characteristic of an environment of the IC package via the channel.

17. A package substrate for an integrated circuit (IC) package, the package substrate comprising:
a glass core having a first surface and a second surface opposite the first surface;
a first build-up region on the first surface of the glass core;
a second build-up region on the second surface of the glass core; and
a micro electromechanical system (MEMS) die between the first build-up region and the second build-up region, the glass core closer to the first build-up region than the MEMS die is to the first build-up region, the glass core closer to the second build-up region than the MEMS die is to the second build-up region.

18. (canceled)

19. The package substrate of claim 17, wherein at least one surface of the MEMS die is in contact with the glass core.

20.-26. (canceled)

27. An apparatus comprising:
a first glass substrate;
a micro electromechanical system (MEMS) die positioned on a surface of the first glass substrate; and
a second glass substrate mounted to the first glass substrate, the MEMS die to be between the first and second glass substrates.

28. The apparatus of claim 27, wherein the MEMS die is a first MEMS die, further including a second MEMS die positioned on the surface of the first glass substrate, the second MEMS die spaced apart from the first MEMS die.

29. The apparatus of claim 27, wherein the surface is a first surface, further including:
a through glass via (TGV) extending through the first glass substrate between the first surface and a second surface of the first glass substrate, the second surface facing away from the first surface of the first glass substrate; and
a build-up layer positioned on the second surface of the first glass substrate, the TGV to electrically couple the MEMS die to the build-up layer.

30. The apparatus of claim 29, wherein the build-up layer is a first build-up layer and the TGV is a first TGV, further including:
a second TGV extending through the first glass substrate and the second glass substrate between the second surface and a third surface of the second glass substrate, the third surface facing away from the second surface of the first glass substrate; and
a second build-up layer positioned on the third surface of the second glass substrate, the second TGV to electrically couple the first build-up layer to the second build-up layer.

31. (canceled)
